(19) United States
(12) Patent Application Publication
(10) Pub. No.: US 2022/0187505 A1
(43) Pub. Date: Jun. 16, 2022

(54) MICROLENS ARRAY OF POLYGONAL PATTERN AND DISPLAY DEVICE INCLUDING THE SAME

(71) Applicant: LG Display Co., Ltd., Seoul (KR)

(72) Inventors: Min-Gyu CHOI, Paju-si (KR); Se-Jin LEE, Paju-si (KR); Dong-Hyeok KIM, Paju-si (KR)

(73) Assignee: LG Display Co., Ltd., Seoul (KR)

(21) Appl. No.: 17/546,973

(22) Filed: Dec. 9, 2021

(30) Foreign Application Priority Data
Dec. 16, 2020 (KR) 10-2020-0176457

(51) Int. Cl. G02B 3/00

(52) U.S. Cl. CPC G02B 3/0043; H01L 51/5275; G02B 3/0056

(57) ABSTRACT

A display device includes a display panel including a plurality of pixel regions and configured to display a picture or an image, and a microlens array disposed on a front surface of the display panel. The microlens array includes a plurality of microlenses each having a polygonal pattern. Further, the microlenses can have different slanted angles.

### CROSS REFERENCE TO RELATED APPLICATIONS

The present application claims the priority benefit of Korean Patent Application No. 10-2020-0176457 filed in Republic of Korea on Dec. 16, 2020, the entire contents of which are hereby expressly incorporated by reference in its entirety for all purposes as if fully set forth herein into the present application.

### BACKGROUND

### Field of the Invention

The present invention relates to a microlens array of polygonal pattern and a display device including the same, and particularly, to a microlens array of polygonal pattern and a display device including the same which can improve a brightness and make no moire happen in a shot picture for inspection.

### Discussion of the Related Art

Flat display devices have been applied to a mobile electronic device, such as a mobile phone, a tablet PC and a laptop computer, and a large-size electronic device, such as a TV, as well.

Recently, flat display devices having a high display quality, such as a high brightness and a high contrast ratio, have been produced by much research. However, there can be a limit in realizing a display quality having a level of a digital cinema or the like.

Further, flat display devices as display devices for mobile devices are much used indoor and outdoor as well, and in case that the flat display devices are used under a brightness environment outside, there may be a limitation that a visibility can be reduced by a limit of a brightness.

### SUMMARY OF THE INVENTION

Accordingly, the present invention is directed to a microlens array of polygonal pattern and a display device including the same that substantially obviate one or more of the problems due to limitations and disadvantages of the related art.

An advantage of the present invention is to provide a microlens array of polygonal pattern and a display device including the same which can have a high brightness, improve a visibility, and make no moire happen in a picture shot by an inspection apparatus to inspect a picture of the display device.

Additional features and advantages of the invention will be set forth in the description which follows, and in part will be apparent from the description, or can be learned by practice of the invention. These and other advantages of the invention will be realized and attained by the structure particularly pointed out in the written description and claims hereof as well as the appended drawings.

To achieve these and other advantages and in accordance with the purpose of the present invention, as embodied and broadly described herein, a display device includes a display panel having a plurality of pixel regions and configured to display a picture or an image, and a microlens array disposed on a front surface of the display panel. The microlens array can include a plurality of microlenses each having a polygonal pattern, and the microlenses can have different slanted angles.

In another aspect, a microlens array includes a base film attached to a display panel configured to display a picture or an image, and a plurality of microlenses disposed on the base film. Each of the microlenses can have a polygonal pattern and can have a slanted angle different from another one of the microlenses.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a cross-sectional view illustrating a schematic structure of a display device according to a first embodiment of the present invention;

FIG. 2 is a cross-sectional view illustrating a structure of a microlens array of a display device according to a first embodiment of the present invention;

FIG. 3 is a perspective view illustrating a polygonal-patterned microlens of the microlens array of FIG. 2;

FIG. 4A is a view illustrating a reflection of an external light for an organic light emitting display device with a microlens array in which semicircular-shaped microlenses are formed;

FIG. 4B is a view illustrating a reflection of an external light for an organic light emitting display device with a microlens array in which polygonal-patterned microlenses are formed according to the first embodiment of the present invention;

FIG. 5 is a cross-sectional view illustrating a detailed structure of a display device according to the first embodiment of the present invention;

FIG. 6 is a cross-sectional view illustrating another detailed structure of a display device according to the first embodiment of the present invention;

FIGS. 7A to 7D are views illustrating actual screens according to angles of a bottom surface and a side surface of a microlens of a display device according to the first embodiment of the present invention;

FIG. 8 is a cross-sectional view schematically illustrating a structure of a display device according to a second embodiment of the present invention;

FIG. 9 is a view illustrating a plane structure and a cross-sectional structure of a display panel and a microlens array according to the second embodiment of the present invention;

FIG. 10 is a view illustrating a microlens array according to the second embodiment of the present invention;

FIG. 11 is a view illustrating a method of inspecting a display device by an inspection apparatus;

FIG. 12 is a view illustrating a moire happening in a picture shot by an inspection apparatus;

FIG. 13 is a view illustrating a microlens array, in which microlenses having 2 different slanted angles are formed, as another structure of a microlens array of a display device according to the second embodiment of the present invention;

FIG. 14A is a view illustrating a brightness of a picture displayed on a display device in case of microlenses of a microlens array all having equal slanted angles;

FIG. 14B is a view illustrating a brightness of a picture displayed on a display device in case of microlenses of a microlens array having 2 different slanted angles;

FIG. 14C is a view illustrating a brightness of a picture displayed on a display device in case of microlenses of a microlens array having 3 different slanted angles;

FIG. 15A is a view illustrating a shot picture in case of the microlenses of a microlens array all having equal slanted angles;

FIG. 15B is a view illustrating a shot picture in case of the microlenses of a microlens array having 2 different slanted angles;

FIG. 15C is a view illustrating a shot picture in case of the microlenses of a microlens array having 3 different slanted angles;

FIG. 16A is a view illustrating a shot picture of an inspection apparatus in case of first to third microlenses being distributed at a ratio of 0%:0%:100%;

FIG. 16B is a view illustrating a shot picture of an inspection apparatus in case of first to third microlenses being distributed at a ratio of 5%:5%:90%;

FIG. 16C is a view illustrating a shot picture of an inspection apparatus in case of first to third microlenses being distributed at a ratio of 10%:10%:80%; and

FIG. 16D is a view illustrating a shot picture of an inspection apparatus in case of first to third microlenses 384a, 384b and 384c being distributed at a ratio of 15%:15%:70% .

### DETAILED DESCRIPTION OF THE EMBODIMENTS

Reference will now be made in detail to exemplary embodiments, examples of which are illustrated in the accompanying drawings. The same reference numbers can be used throughout the drawings to refer to the same or like parts.

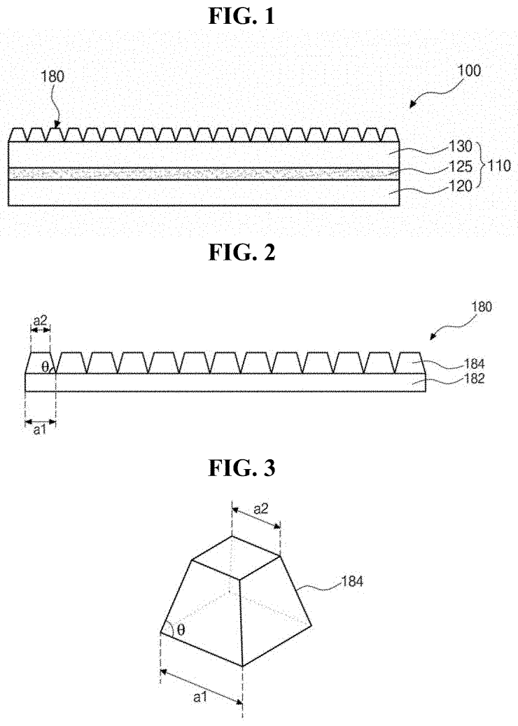

FIG. 1 is a view illustrating a display device 100 according to a first embodiment of the present invention. Further, all the components of each display device and each microlens array according to all embodiments of the present invention are operatively coupled and configured.

Referring to FIG. 1, the display device 100 can include a display panel 110 and a microlens array 180 which is located on a front surface of the display panel 110, i.e., a surface of the display panel 110 which a picture, image or other content is displayed on.

The display panel 110 can be, but not limited to, a liquid crystal panel, an organic light emitting display panel, an electrophoresis display panel, a mini LED (light emitting diode) display panel or a micro LED display panel. However, the display panel 110 can be one of various other display panels currently known.

Further, the display panel 110 can be a tiled type display panel which is formed with a plurality of panels arranged in a tiling manner.

The display panel 110 can include a first substrate 120 and a second substrate 130 and a display element 125 between the first substrate 120 and the second substrate 130. The first and second substrates 120 and 130 can be formed of a hard transparent material such as a glass, or a flexible transparent material such as a plastic film.

A plurality of gate lines and a plurality of data lines which are respectively arranged in a row direction and a column direction and define a plurality of pixel regions can be formed at the first substrate 120, a thin film transistor as a switching element can be formed in each pixel region, and a pixel electrode can be formed on the pixel region.

Further, the thin film transistor can include a gate electrode connected to the gate line, a semiconductor layer which is made of amorphous silicon, crystalline silicon or oxide semiconductor stacked on the gate electrode, and source and drain electrodes which are formed on the semiconductor layer and are respectively connected to the data line and the pixel electrode.

In case that the display panel 110 is an organic light emitting display panel, the display element 125 can include an organic light emitting element. The organic light emitting element can include a pixel electrode (or a first electrode), an organic emitting layer on the first electrode, and a second electrode on the organic emitting layer. The first electrode can be an anode or a cathode. Further, the second electrode can be an anode or a cathode which is different from the first electrode.

In case that the display panel 110 is a liquid crystal display panel, the display element 125 can include a liquid crystal layer. In case that the display panel 110 is an electrophoresis display panel, the display element 125 can include an electrophoresis layer. Further, in case that the display panel 110 is a mini LED display panel or a micro LED display panel, the display element 125 can include a mini LED or a micro LED.

In case that the display panel 110 is an organic light emitting display panel, an encapsulation layer which is able to block a penetration of a moisture or a foreign substance from the outside can be formed on the organic emitting layer. The encapsulation layer can be configured with at least one inorganic layer and at least one organic layer such as inorganic layer/organic layer or inorganic layer/organic layer/organic layer. The second substrate 120 can be formed of a transparent film such as a polystyrene (PS) film, a polyethylene (PE) film, a polyethylene naphthalate (PEN) film, or a polyimide (PI) film.

In case that the display panel 110 is a liquid crystal display panel, a color filter which is configured with a plurality of sub-color filters realizing a red (R) color, a green (G) color and a blue (B) color, a black matrix which divides between the sub-color filters and block a light passing through a liquid crystal layer, and a common electrode can be formed at the second substrate 130. At least one of the color filter and the common electrode can be formed at the first substrate 120.

As the microlens array can be located on a front surface (or a picture display surface) of the display panel 110 and can improve a brightness of a picture, the microlens array is explained below in detail.

FIG. 2 is a view illustrating the microlens array 180 of the display device 100 according to the first embodiment of the present invention.

Referring to FIG. 2, the microlens array 180 can include a base film 182, and a plurality of microlenses 184 formed on a top surface of the base film 182.

The base film 182 can be formed of a transparent film such as a polyethylene terephthalate (PET) film, and the plurality of microlenses 184 can be formed of a transparent resin material. However, the base film 182 and the plurality of microlenses 184 are not limited to the above materials but can be formed of other material.

Referring to FIG. 3, each of the microlenses 184 can be formed to have a quadrangular pattern such that a side surface is slanted at a predetermined slanted angle θ and a width a1 of a bottom surface is greater than a width a2 of a top surface (a1>a2), i.e., an area of the bottom surface is greater than an area of the top surface. However, the microlenses 184 are not limited to the quadrangular pattern but can have other polygonal pattern such as a triangular pattern, a pentagonal pattern or a hexagonal pattern.

The base film 182 can be configured to have the same area as the display panel 110, and the microlenses 184 can be arranged at equal angles and equal pitches over an entire region of the base film 182. In other words, the microlenses 184 can be arranged with equal shapes at predetermined pitches all over the base film 182.

The microlens array 180 can be attached on the top surface of the display panel 110 by a transparent adhesive such as an optical clear adhesive (OCA) or an optical clear resin (OCR). Further, the microlenses 184 of the microlens array 180 can be formed directly on the top surface of the display panel 110 without the base film 182. In this case, the microlenses 184 can be formed by a photolithography process of coating the top surface of the display panel 110 with a transparent resin and then using a photoresist, or by coating the top surface of the display panel 110 with a photosensitive resin and then irradiating the photosensitive resin to directly remove a part of the photosensitive resin.

As described above, by arranging the microlens array 180 on the front surface of the display panel 110, a brightness of the display device 100 can be improved, and the reason is as follows. For the purpose of explanations, an organic light emitting display panel is described below by way of example, but other display panel can have an improved brightness.

In case of an organic light emitting display device not including the microlens array 180, because a refractive index of the second substrate 130 made of a glass is 1.5 and a refractive index of an external air is 1.0, a light which is incident at a critical angle or more when a light goes outside is isolated inside the second substrate 130. Because a ratio of the isolated light to a light emitted from the organic light emitting display device can reach about 35%, a brightness of the display device 100 is reduced.

However, in case of an organic light emitting display device 100 including the microlens array 180, an incident angle of a light output from the display panel 110 with a tangent line of a surface of the microlens 184 is less than an incident angle of a light on the second substrate 130. In other words, because an incident angle of a light with a tangent line of the microlens 184 is less than a critical angle, a light is all extracted to the outside rather than trapped inside the second substrate 130 due to a total reflection. Thus, a brightness can be improved.

Further, because the microlens array 180 is formed in a polygonal pattern shape, a brightness of the display device 100 can be further improved. In other words, in this embodiment of the present invention, because a side surface of the microlens 184 is slanted at a predetermined angle, an amount of a light incident which is on the side surface of the microlens 184 increases from a bottom of the microlens 184 to a top of the microlens 184. Accordingly, because an amount of a light, a total reflection of which is broken, increases from the bottom of the microlens 184 to the top of the microlens 184, an amount of a light, which is extracted to the outside rather than trapped inside the second substrate 130 due to a total reflection, further increases. Thus, a brightness can be further improved.

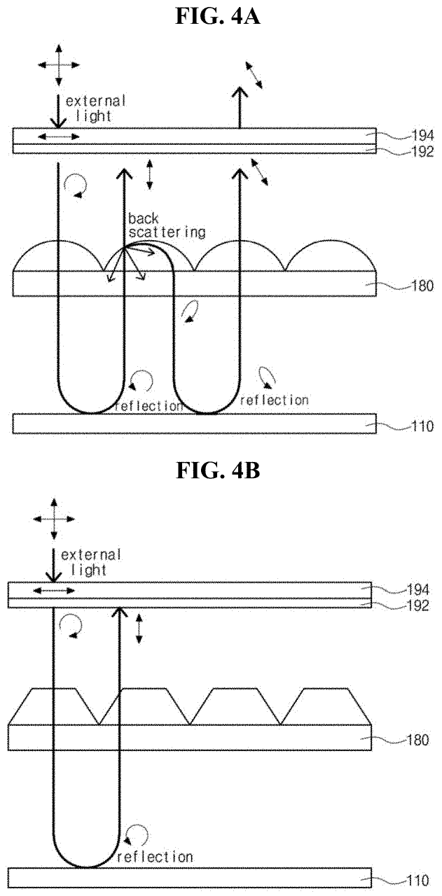

FIG. 4A is a view illustrating a reflection of an external light for an organic light emitting display device with a microlens array in which semicircular-shaped microlenses are formed, and FIG. 4B is a view illustrating a reflection of an external light for an organic light emitting display device with a microlens array in which polygonal-patterned microlenses are formed according to the first embodiment of the present invention. For the purpose of explanations, the display panel 110 and the microlens array 180 are shown simply.

Referring to FIG. 4A, on the display panel 110 including the semicircular-shaped microlenses 184, λ/4 phase retardation plate 192 and a polarization plate 194 to prevent a reflection of an external light are located.

A light, which is incident on the display device 100 from the outside, is linearly polarized in a first direction by the polarization plate 194 having an optical transmission axis of a first direction (e.g., an x direction), then is changed into a circularly polarized light in a third direction (e.g., a right-circular direction) through the phase retardation plate 192, then pass through the microlens array 180 including the semicircular-shaped microlenses 184, and then is input to the display panel 110.

The external light input to the display panel 110 is reflected by a reflective structure such as a variety of electrodes or lines formed in the display panel 110. By this reflection, a circularly polarized light in the third direction is circularly polarized in a fourth direction (e.g., a left-circular direction) opposite to the third direction and then is output outside the display panel 110.

The light output outside the display panel 110 is transmitted through the microlens array 180, and then is input to the phase retardation plate 192 and the polarization plate 194 again. The phase retardation plate 192 changes the circularly polarized light in the fourth direction into a linearly polarized light. At this time, the light is linearly polarized in a second direction (e.g., a y direction) perpendicular to the first direction. Because the polarization plate 194 has the optical transmission axis of the first direction, the linearly polarized light in the second direction is all absorbed by the polarization plate 194 while passing through the polarization plate 194 and is not transmitted to the outside.

Accordingly, because the external light is absorbed by the polarization plate 194 even in the display device 100 in which the microlens array 180 including the semicircular-shaped microlenses 184 is located, the external light is not recognized by a user.

However, in the display device 100 in which the microlens array 180 including the semicircular-shaped microlenses 184 is located, when a light is reflected by the display panel 110 and then is transmitted through the semicircular-shaped microlens 184 again, the light is diffused and a back scattering happens due to the diffusion.

Because the back scattering changes a polarization state of a light, a light input to the display panel 110 is changed from a circularly polarized light into an elliptically polarized light in the third direction.

The elliptically polarized light in the third direction is reflected by a reflection structure of the display panel 110 again then is changed into an elliptically polarized light in the fourth direction and then is input to the phase retardation plate 192. The phase retardation plate 192 changes the elliptically polarized light into a linearly polarized light. Because the elliptically polarized light is linearly polarized, the light input to the phase retardation plate 192 is linearly polarized not in the second direction but in a direction between the first direction and the second direction (e.g., in a direction having a predetermined angle made between the first direction and the second direction).

Accordingly, a light output from the phase retardation plate 192 is not entirely absorbed by the polarization plate 194 but is partially transmitted through the polarization plate 194 and then is recognized to a user.

As described above, in the display device 100 with the microlens array 180 in which the semicircular-shaped microlenses 184 is formed, a part of an external light is reflected by a surface, a visibility is reduced.

However, referring to FIG. 4B, in the display device 100 with the microlens array 180 in which the polygonal-patterned microlenses 184 is formed according to the first embodiment of the present invention, a light, which is incident on the display device 100 from the outside, is linearly polarized in a first direction by the polarization plate 194 having an optical transmission axis of the first direction, then is changed into a circularly polarized light in the third direction through the phase retardation plate 192, then pass through the microlens array 180 including the polygonal-patterned microlenses 184, and then is input to the display panel 110.

The external light input to the display panel 110 is reflected by a reflective structure formed in the display panel 110. By this reflection, a circularly polarized light in the third direction is circularly polarized in the fourth direction opposite to the third direction and then is output outside the display panel 110.

The light output outside the display panel 110 is transmitted through the microlens array 180, and then is input to the phase retardation plate 192 and the polarization plate 194 again. The phase retardation plate 192 changes the circularly polarized light in the fourth direction into a linearly polarized light. At this time, the light is linearly polarized in the second direction perpendicular to the first direction. Because the polarization plate 194 has the optical transmission axis of the first direction, the linearly polarized light in the second direction is all absorbed by the polarization plate 194 while passing through the polarization plate 194 and is not transmitted to the outside.

In this organic light emitting display device 100, a diffusion of a light is slight while the light is transmitted through the polygonal-patterned microlens 184. Accordingly, a back scattering does not happen, thus a change of a circularly polarized light into an elliptically polarized light due to the scattering does not happen, and thus a part of a light being transmitted through the polarization plate 194 can be prevented.

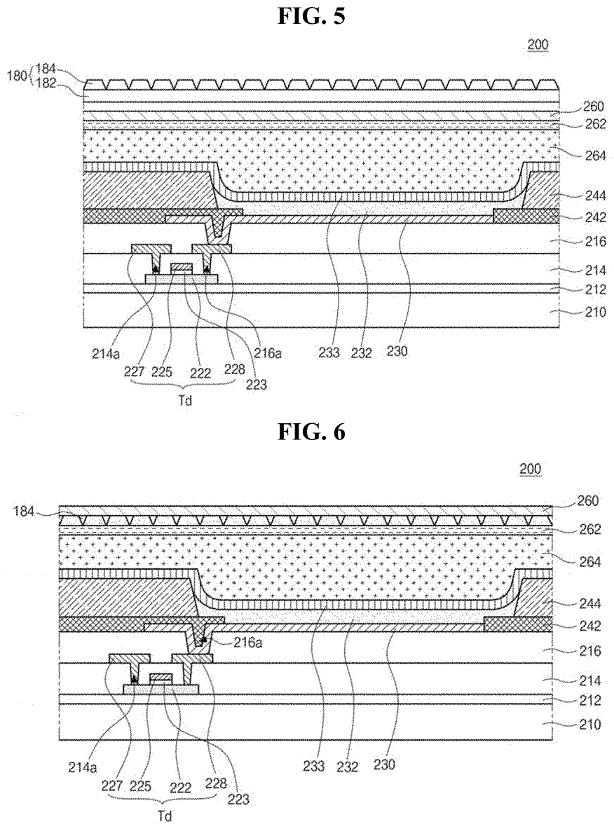

FIG. 5 is a cross-sectional view illustrating a detailed structure of a display device 200 according to the first embodiment of the present invention. The display device 200 of FIG. 5 is an organic light emitting display device by way of example. However, the present invention is not limited to the organic light emitting display device but can be applied to a liquid crystal display device, a mini LED display device, a micro LED display device, a tiled type display device with a plurality of display panels arranged in a tiling manner.

Referring to FIG. 5, a buffer layer 212 can be formed on a first substrate 210, a driving thin film transistor Td can be located on the buffer layer 212. The substrate 210 can be formed of a transparent material such as glass, or a transparent and flexible plastic such as polyimide. The buffer layer 212 can be formed with a single layer or multiple layers using an inorganic material such as silicon oxide (SiOx) or silicon nitride (SiNx).

The driving thin film transistor Td can be formed in each of a plurality of pixels. The driving thin film transistor Td can include a semiconductor layer 222 formed in the pixel on the buffer layer 212, a gate insulating layer 223 formed on a portion of the semiconductor layer 222, a gate electrode 225 formed on the gate insulating layer 223, an inter-layered insulating layer 214 formed entirely over the substrate 210 to cover the gate electrode 225, and source and drain electrodes 227 and 228 contacting the semiconductor layer 222 through respective first contact holes 214a formed in the inter-layered insulating layer 214.

Further, a switching thin film transistor can be formed on the first substrate 210. The switching thin film transistor can have the same structure as the driving thin film transistor Td.

The semiconductor layer 222 can be formed of amorphous silicon, crystalline silicon, or an oxide semiconductor such as indium gallium zinc oxide (IGZO). The semiconductor layer 222 can include a channel layer as a center region thereof and doping layers at both side regions thereof, and the source and drain electrodes 227 and 228 can contact the respective doping layers.

The gate electrode 225 can be formed of a metal such as Cr, Mo, Ta, Cu, Ti, Al or an alloy with an Al alloy. The gate insulating layer 223 and the inter-layered insulating layer 214 can be formed as an inorganic layer which is configured with a single layer of an inorganic insulating material such as silicon oxide (SiOx) or silicon nitride (SiNx), or with double layers of SiOx and SiNx. The source and drain electrodes 227 and 228 can be formed of Cr, Mo, Ta, Cu, Ti, Al or an Al alloy.

In the drawings and the above explanations, the driving thin film transistor Td with a specific structure is shown by way of example. However, the driving thin film transistor Td of the present invention is not limited to the shown specific structure but can have other structure.

A passivation layer 216 can be formed on the substrate 210 having the driving thin film transistor Td. The passivation layer 216 can be formed of an organic material such as photo acryl, or can be formed with a plurality of layers including an inorganic layer and an organic layer. A second contact hole 216a can be formed in the passivation layer 216.

A first electrode 230 can be formed on the passivation layer 216 and be electrically connected to the drain electrode 228 of the driving thin film transistor Td through the second contact hole 216a . The first electrode 230 can be formed with a single layer or multiple layers using Ca, Ba, Mg, Al, Ag and/or and an alloy thereof. The first electrode 230 can contact the drain electrode 228 and be applied with a picture signal.

A first bank layer 242 and a second bank layer 244 can be formed at a boundary of each pixel on the passivation layer 216. The first bank layer 242 and the second bank layer 244 can be a kind of separation wall, and can divide pixels and prevent specific color lights output from adjacent pixels from being mixed and output. In FIG. 5, the first bank layer 242 being formed on the passivation layer 216 and the second bank layer 242 being formed on the first bank layer 242 is shown by way of example. However, the first bank layer 242 can be formed on the first electrode 230. Further, the first electrode 230 can extend on side surfaces of the first and second bank layers 242 and 244.

An organic emitting layer 232 can be formed on the first electrode 230 and the first and second bank layers 242 and 244. The organic emitting layer 232 can be an R organic emitting layer emitting a red light, a G organic emitting layer emitting a green light or a B organic emitting layer emitting a blue light, which is formed in a corresponding R, G or B pixel. Further, the organic emitting layer 232 can be a W organic emitting layer emitting a white light.

The organic emitting layer 232 can include an emitting layer and further an electron injection layer and a hole injection layer respectively injecting electrons and holes, and an electron transporting layer and a hole transporting layer respectively transporting the injected electrons and holes to the emitting layer.

A second electrode 234 can be formed on the organic emitting layer 232. The second electrode 234 can be formed of, but not limited to, a transparent conductive material such as ITO (indium tin oxide) or IZO (indium zinc oxide), or a thin metal which transmits a visible light. An encapsulation layer 264 can be formed on the second electrode 234. The encapsulation layer 264 can be configured with a single layer of an inorganic layer, double layers of inorganic layer/organic layer, or triple layers of inorganic layer/organic layer/inorganic layer. The inorganic layer can be formed of an inorganic material, for example, but not limited to, SiNx or SiNx. The organic layer can be, for example, but not limited to, polyethylene terephthalate, polyethylene naphthalate, polycarbonate, polyimide, polyethylene sulfonate, polyoxymethylene, polyarylate, or a mixture thereof.

A color filter layer 262 can be formed on the encapsulation layer 264. The color filter layer 262 can be an R, G or B color filter layer.

A second substrate 260 can be located on the color filter layer 262 and can be attached to the color filter layer 262 by an adhesive layer. The adhesive layer can use any material which has a good adhesiveness, a good heat-resistance and a good water-resistance. In the present invention, the adhesive layer can use a thermosetting resin such as an epoxy compound, an acrylate compound or an acryl rubber. The adhesive layer can use a photo-curable resin, and in this case, a light such as an ultraviolet light irradiates the adhesive layer to harden the adhesive layer.

The adhesive layer can serve to attach the first substrate 210 to the second substrate 260 and serve as an encapsulation member to prevent a penetration of a moisture inside the organic light emitting display device as well.

As the second substrate 260 can serve as an encapsulation cap to encapsulate the organic light emitting display device, the second substrate 260 can use a protection film such as a polystyrene (PS) film, a polyethylene (PE) film, a polyethylene naphthalate (PEN) film or a polyimide (PI) film, or a glass.

A planarization layer can be formed between the second electrode 234 and the color filter layer 262. The planarization layer can be formed of an organic layer and be configured with multiple layers using an inorganic layer and an organic layer. For example, the inorganic layer can use, but not limited to, SiOx or SiNx, and the organic layer can use, but not limited to, photo acryl.

A microlens array 180 can be attached onto the second substrate 260. The microlens array 180 can include a base film 182 and polygonal-patterned microlenses 184 located on the base film 182.

The microlens array 180 can be attached to the second substrate 260 by an adhesive such as an OCR or OCA.

The first electrode 230, the organic emitting layer 232 and the second electrode 234 can form an organic emitting element.

The first electrode 230 can be a cathode of the organic emitting element and the second electrode can be an anode of the organic emitting element. When voltages are applied to the first electrode 230 and the second electrode 234, an electron from the first electrode 230 is injected to the organic emitting layer 232 and a hole from the second electrode 234 is injected to the organic emitting layer 232 so that an exciton is produced in the organic emitting layer 232. As the exciton is decayed, a light of an energy difference between a LUMO (lowest unoccupied molecular orbital) and a HOMO (highest occupied molecular orbital) of the emitting layer is produced and emitted to the outside (e.g., toward the second substrate 260).

Further, the organic emitting element can be configured such that the first electrode 230 is formed of a transparent conductive material or a thin metal transmitting a visible light and the second electrode 234 is formed of a single layer or multiple layers using Ca, Ba, Mg, Al, Ag or an alloy thereof, and a light produced in the organic emitting layer 232 can be emitted to the outside (e.g., toward the first substrate 210).

As such, in case that a light produced in the organic emitting layer 232 is emitted toward the first substrate 210, a screen displaying a picture of the display device 200 is a first substrate 210, and the microlens array 180 is attached to the first substrate 210 which an actual picture is displayed.

In the display device 200 of the first embodiment, as the microlens array 180 is attached to the second substrate 260 and the first substrate 210, a brightness of a picture displayed from the display device 200 can be improved and a reflection of an external light can be minimized as well.

However, the present invention is not limited to this structure but can be configured with other structure.

In other words, in some examples of the present invention, the microlens array 180 may not be attached to the first substrate 210 or the second substrate 260 in a film type, but a transparent resin can be deposited on an outer surface of the first substrate 210 or the second substrate 260 and be patterned by a photolithography process so that polygonal-patterned microlenses 184 can be formed directly on the outer surface of the first substrate 210 or the second substrate 260.

Further, the microlenses 184 can be formed directly in the display panel.

FIG. 6 is a cross-sectional view illustrating another detailed structure of a display device 200 according to the first embodiment of the present invention. Because the display device 200 of FIG. 6 has a structure similar to that of the display device of FIG. 5, explanations of the same parts may be omitted or simplified, and different parts are explained in detail.

Referring to FIG. 6, in each of pixels P divided by a first bank layer 242 and a second bank layer 244, an organic light emitting element including a first electrode 230, an organic emitting layer 232 and a second electrode 233 can be formed, and an encapsulation layer 264 and a color filter layer 262 can be formed on the organic emitting element.

Polygonal-patterned microlenses 184 can be formed on the color filter layer 262. The microlens 184 can be formed by depositing a transparent resin on the color filter layer 262 and patterning the transparent resin in a photolithography process. The polygonal-patterned microlenses 184 can be coated with an adhesive layer so that a second substrate 260 can be attached to the polygonal-patterned microlenses 184.

Further, the polygonal-patterned microlenses 184 may not be formed on the color filter layer 262 but can be formed on the encapsulation layer 264.

As described above, in the display device 100 according to the first embodiment of the present invention, by locating the microlens array 180 with the polygonal-patterned microlenses 184 on the front surface of the display panel 110, a brightness of the display device 100 can increase, and a reduction of visibility due to a reflection of an external light can be prevented. Further, in the display device 100 according to the first embodiment of the present invention, an image blur can be improved.

Particularly, by using the polygonal-patterned microlens instead of the semicircular-shaped microlens, a reflection of an external light can be minimized and an image blur can be minimized.

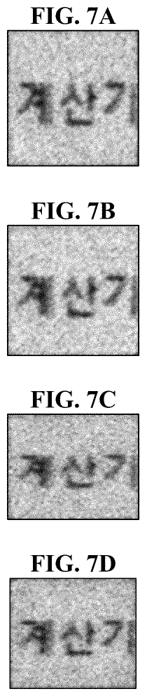

Table 1 shows brightnesses, reflation rates of external light, image blurs according to angles θ of a bottom surface a2 and a side surface of a microlens in a display device with a polygonal-patterned microlens, and FIGS. 7A to 7D are views illustrating an example of actual screens (showing some Korean text as a mere example of an image) according to angles θ of a bottom surface a2 and a side surface of a microlens.

In this regard, in case of the polygonal-patterned microlens according to the first embodiment of the present invention, a width of the bottom surface a2 is 10 um, a height is 1 um, angles θ of the bottom surface a2 and the side surface are 60 degrees, 45 degrees, 30 degrees and 15 degrees. Further, FIGS. 7A to 7D respectively show actual screens at the angles θ of 60 degrees, 45 degrees, 30 degrees and 15 degrees.

TABLE 1

| | | Reflection rate of | |
|---|---|---|---|
| θ | Brightness (%) | external light (%) | Level of image blur |
| 60° | 110 | 2.92 | Little |
| 45° | 114 | 3.32 | Little |
| 30° | 123 | 3.57 | Weak |
| 15° | 135 | 3.94 | Weak |

As shown in Table 1, when the angle θ of the polygonal-patterned microlens is 60 degrees, the brightness of the display device is 110%, the reflection rate of external light is 2.92%, the level of image blur is ‘little.’ Accordingly, as shown in FIG. 7A, compared with the display device with no microlens, in the display device with the polygonal-patterned microlens of this structure, the brightness increases, and the reflection rate of externa light and the level of image blur are greatly improved.

When the angle θ of the polygonal-patterned microlens is 45 degrees, the brightness of the display device is 114%, the reflection rate of external light is 3.32%, the level of image blur is ‘little.’ Accordingly, as shown in FIG. 7B, even in the display device with the polygonal-patterned microlens of this structure, the brightness increases, and the reflection rate of externa light and the level of image blur are greatly improved.

When the angle θ of the polygonal-patterned microlens is 30 degrees, the brightness of the display device is 123%, the reflection rate of external light is 3.57%, the level of image blur is ‘weak.’ Accordingly, as shown in FIG. 7C, even in the display device with the polygonal-patterned microlens of this structure, the brightness greatly increases, and the reflection rate of externa light and the level of image blur are improved.

When the angle θ of the polygonal-patterned microlens is 15 degrees, the brightness of the display device is 135%, the reflection rate of external light is 3.94%, the level of image blur is ‘weak.’ Accordingly, as shown in FIG. 7D, even in the display device with the polygonal-patterned microlens of this structure, the brightness greatly increases, and the reflection rate of externa light and the level of image blur are improved.

As such, in the display device 200 according to the first embodiment of the present invention, as the angle θ of the polygonal-patterned microlens decreases, the brightness increases to 110%, 114%, 123% and 135% and gets better, the reflection rate of external light increases to 2.92%, 3.32%, 3.57% and 3.94% and gets worse, and the level of image blur gets worse to ‘little,’ ‘little,’ ‘weak,’ and ‘weak.’

In other words, in the display device 200 according to the first embodiment of the present invention, as the angle θ of the polygonal-patterned microlens decreases, a high brightness can be realized but the level of image blur gets worse. Thus, in order to realize a high display quality, a range θ of the angle of the polygonal-patterned microlens needs to be designed appropriately.

An important factor, which is recognized most to a user among various factors of display quality and determines a display quality of picture, is a brightness. Further, in the display device 200 according to the first embodiment of the present invention, an increase rate of brightness according to a decrease of the angle θ of the polygonal-patterned microlens is much greater than a reflection rate of external light and a decrease rate of image blur.

Accordingly, in the display device 200 according to the first embodiment of the present invention, the angle θ of the polygonal-patterned microlens being set at about 10 degrees to about 50 degrees is preferred in the light of realization of a high brightness and improvement of a reflection rate of external light and improvement of image blur.

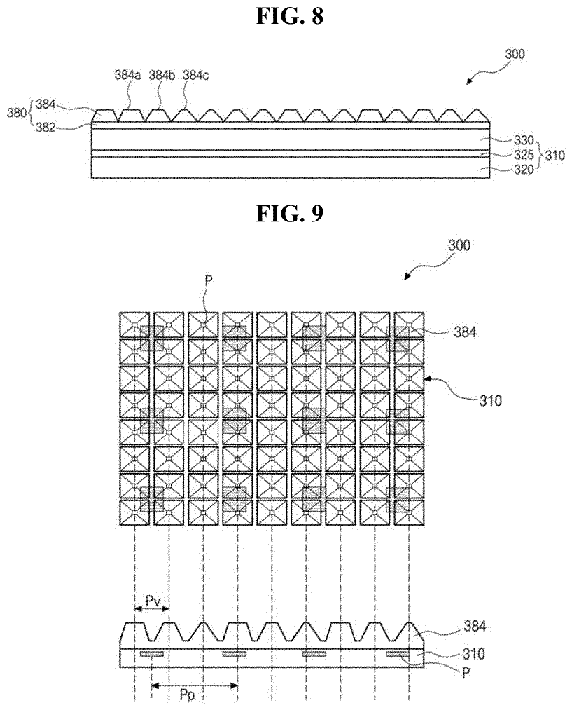

FIG. 8 is a view schematically illustrating a structure of a display device 300 according to a second embodiment of the present invention.

Referring to FIG. 8, the display device 300 according to the second embodiment of the present invention can include a display panel 310 and a microlens array 380 located on the display panel 310.

The display panel 310 can be, but not limited to, a liquid crystal panel, an organic light emitting display panel, an electrophoresis display device, a mini LED display panel or a micro LED display panel. However, the display panel 110 can be one of various other display panels currently known. Further, the display panel 310 can be a tiled type display panel which is formed with a plurality of panels arranged in a tiling manner.

The display panel 310 can include a first substrate 320 and a second substrate 330 and a display element 325 between the first substrate 320 and the second substrate 330. In case that the display panel 310 is an organic light emitting display panel, the display element 325 can include an organic light emitting element. In case that the display panel 310 is a liquid crystal display panel, the display element 325 can include a liquid crystal layer. In case that the display panel 310 is an electrophoresis display panel, the display element 325 can include an electrophoresis layer. Further, in case that the display panel 310 is a mini LED display panel or a micro LED display panel, the display element 325 can include a mini LED or a micro LED.

The microlens array 380 can include a base film 382, and a plurality of polygonal-patterned microlenses 384 formed on a top surface of the base film 382. The base film 382 can be formed of, but not limited to, a transparent film such as a PET film, and the plurality of microlenses 184 can be formed of, but not limited to, a transparent resin.

The microlenses 384 can be formed to have a quadrangular pattern such that a side surface is slanted at a predetermined angle and an area of a bottom surface is different from an area of a top surface. However, the microlenses 384 are not limited to the quadrangular pattern but can have other polygonal pattern such as a triangular pattern, a pentagonal pattern or a hexagonal pattern.

In the drawings, the microlenses 384 are formed on the base film 382 and are attached to the top surface of the display panel 310. However, the microlenses 384 can be formed directly on the top surface of the display panel 310 or in the display panel 310.

FIG. 9 is a view illustrating a plane structure and a cross-sectional structure of a display panel 310 and a microlens array 380 according to the second embodiment of the present invention.

Referring to FIG. 9, a plurality of pixel regions P can be arranged in a matrix form in the display panel 310. A driving thin film transistor, a switching thin film transistor and an organic light emitting element can be located in each pixel region P, and a single color light of an R, G or B light can be emitted or a white light can be emitted.

It is explained in detail below that a ratio of a pitch of the microlens 384 of the microlens array 380 to a pitch of the pixel region P, i.e., an R, G or B pixel region of the display panel 310 is set to be 0.3946 or less and thus about 2.5 or greater pixel regions P to 1 microlens 384 are arranged.

Further, the polygonal-patterned microlens 384 can be arranged at a region between the pixel regions P, or can be arranged to overlap a part or a whole of the pixel region P.

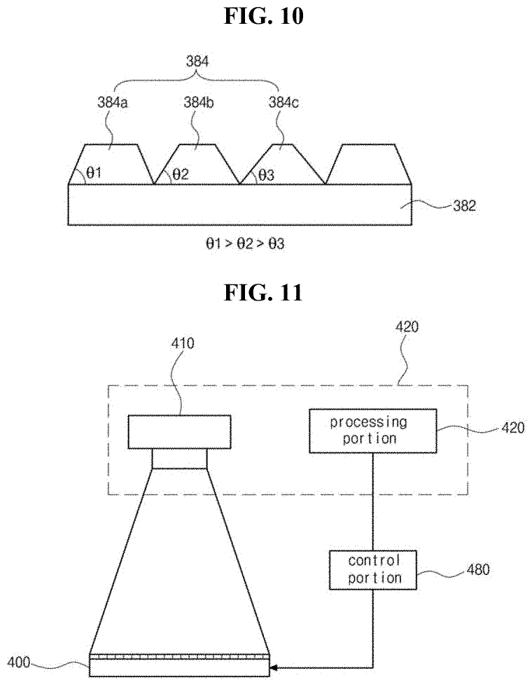

FIG. 10 is a view illustrating the microlens array 380 according to the second embodiment of the present invention.

Referring to FIG. 10, the microlens array 380 can include a base film 382, and a plurality of polygonal-patterned microlenses 384 formed on a top surface of the base film 382.

The microlenses 384 can include a first microlens 384a in which a slanted angle of a side surface with the base film 382 is θ1, a second microlens 384b in which a slanted angle of a side surface with the base film 382 is θ2, and a third microlens 384c in which a slanted angle of a side surface with the base film 382 is θ3. The slanted angles of the side surfaces of the microlenses 384 can have a relation of θ1>θ2>θ3, and θ1 can be 45 degrees, θ2 can be 30 degrees, and θ3 can be 15 degrees. However, the slanted angles θ1, θ2 and θ3 of the first to third microlenses 384a, 384b and 384c are not limited to the above but have other ranges of angle. For example, the slanted angles θ1, θ2 and θ3 of the first to third microlenses 384a, 384b and 384c can be set as following ranges of angle: 40<θ1<50°, 25°<θ2<35°, and 10°<θ3<20°.

In the second embodiment, the microlenses 384 being configured with the first to third microlenses 384a, 384b and 384c having different slanted angles θ1, θ2 and θ3 can be to prevent a moire from happening in a picture shot by an inspection camera when inspecting the display device 300, which is explained in detail below.

FIG. 11 is a view illustrating a method of inspecting a display device 300 by an inspection apparatus 400.

Referring to FIG. 11, the inspection apparatus 400 for the display device 300 can include a shooting member 410 shooting the display device 300, and a processing portion 420 (e.g., a processor) which processes a picture shot by the shooting member 410 and detects a defect such as an abnormality of brightness or a spot.

The shooting member 410 can include a camera, a lens system, a focusing member, and so on. The camera can be a component shooting a picture displayed on the display device 300 and include, but not limited to, a CCD (charged coupled device) camera.

The lens system can be configured with a plurality of lenses and serve to make a picture displayed on the display device 300 into parallel lights and then inputted to the camera. The lens system can include a filter.

The focusing member can move the lens system and the camera together and focus on a picture displayed on the display device 300. The focusing member can be configured with a fixing member fixing the lens and a moving member moving the lens vertically and/or horizontally.

A picture shot by the shooting member 410 can be input to the processing portion 420. The processing portion 420 can process the shot picture input thereto and generate an information of the shot picture, and then can compare the processed information with a setting information and determine a fair quality of a display device or compensate for a picture.

For example, the processed information can be a brightness information. The processed information can be compared with a stored information so that a difference value therebetween can be calculated, and when the difference value is equal to or greater than a first set value, a manufactured display device can be determined to be defective so that the display device can be discarded or a defect of the display device can be removed through a repair process or the like.

When the difference value of the brightness information is greater than the first set value and is equal to or less than a second set value, it can be determined that a defect can be removed with compensating for a picture, and the processing portion 420 can calculate a compensation value corresponding to the difference value and then output the compensation value to a control portion 480 (e.g., controller or processor).

The control portion 480 can convert a picture data, which are supplied from an external system, based on the compensation value input from the processing portion 420, and then supply the converted picture data to a data driving portion. Further, the data driving portion can convert the input picture data into an analog picture signal and then supply the analog picture signal to a data line, and thus a compensated picture can be displayed.

The control portion 480 can be located inside the display device 300 or outside the display device 300.

The inspection apparatus 400 for the display device 300 can shoot a picture displayed on the display panel then process the shot picture, and thus whether the display device 300 is defective or not can be determined and a picture of high quality can be displayed with compensating for the picture.

The inspection of the display device 300 can be performed in various steps. For example, the inspection can be performed after the display panel is completed, or in a step of display module in which a FPCB (flexible printed circuit board), which a gate driving element, a data driving element and the control portion 480 are mounted on, is attached to the display panel.

As described above, the inspection apparatus 400 for the display device 300 can shoot a picture displayed on the display device 300 and detect a defect such as a spot, a fair quality of a picture of the display device 300 can be determined, or a compensation value corresponding to a spot or the like can be calculated and a picture can be compensated for and thus a picture which a defect such as a spot is removed from can be displayed on the display device 300.

However, in case of shooting a picture displayed on the display device 300 by the camera, the picture shot by the camera is different from the picture actually displayed on the display device 300. In other words, because pixels arranged periodically in the display device 300 interferes periodically with optical sensors (i.e., camera sensors) arranged periodically in the camera, a moire, in which a high brightness region and a low brightness region alternate periodically in the shot picture, happens.

Accordingly, a pair quality of a picture of the display device 300 is determined based on the shot picture having the moire or a picture is compensated for based on the shot picture. Thus, an accurate determination of a pair quality is impossible. Further, a spot is not removed from the compensated picture, but due to a false compensation, more spots happen or a moire, in which a high brightness and a low brightness alternate in an actual picture, happens.

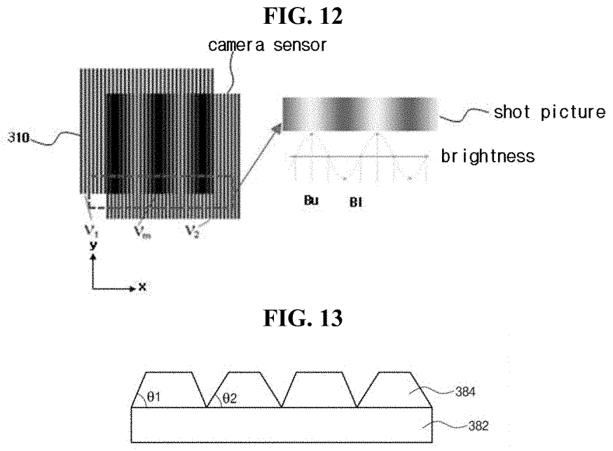

FIG. 12 is a view illustrating an example of a moire happening in a picture shot by an inspection apparatus 400.

Referring to FIG. 12, in the display panel 310 of the display device 300, a plurality of pixel regions are formed in a lattice manner and arranged periodically and repeatedly in x and y directions. Sensors of a camera shooting a picture displayed on the display panel 310 are arranged repeatedly in x and y directions.

The display panel 310 displays a picture having brightnesses corresponding to picture signals at a plurality of pixel regions. In other words, a picture displayed on the display panel 310 has no defect such as a moire. However, in the case that a picture output from the display panel 310 is input to the camera of the shooting member 410, when the picture output from the plurality of pixel regions of the display panel 310 having a periodicity is input to the camera sensors arranged periodically and repeatedly, a moire having a high brightness Bh and a low brightness Bl alternated and repeated happens by the pixel regions arranged periodically and the camera sensors arranged periodically, and the shot picture having the moire is recorded in the camera.

Thus, the processing portion 420 of the inspection apparatus 400 does not process a picture actually displayed on the display device 300 but processes the shot picture having the moire, and then performs a determination of a pair quality and a picture compensation. Accordingly, an accurate determination of a pair quality for the display device 300 and an accurate compensation for the display device 300 are impossible.

In the display device 300 according to the second embodiment of the present invention, the microlenses 384 of the microlens array 380 arranged on the front surface of the display panel 310 can be formed in a polygonal pattern and be configured with the first to third microlenses 384a, 384b and 384c having different slanted angles of side surfaces. Thus, an improvement of a brightness, a reduction of a reflection rate and an improvement of an image blur are realized, and a moire happening in a shot picture when inspecting the display device 300 is prevented and thus an accurate determination of a pair quality for the display device 300 and an accurate compensation of a picture for the display device 300 are possible.

Referring back to FIG. 10, the microlenses 384 can have 3 different shapes, i.e., 3 different slanted angles θ1, θ2 and θ3. In this case, the slanted angles θ1, θ2 and θ3 can be preferably in a range of 40°<θ1<50°, 25°<θ2<35° and 10°<θ3<20°, and can be more preferably θ1=40°, θ2=30° and θ3=15°.

Further, in order for no moire to happen in a shot picture for the display device 300 according to the second embodiment, following conditions can be satisfied.

<First Condition>

The first condition in order for no moire to happen in a shot picture for the display device 300 according to the second embodiment can have a relation of a pitch of the microlens 384 a pitch (or a period) of the pixel region P in the display device 300 as follows:

Pv=1/k*Pp(k≥2.6),

Pv≤0.3846*Pp.

Pv is a pitch of the microlens 384, Pp is a pitch of the pixel region P (i.e., R, G and B sub-pixels), and k=Pp/Pv.

In other words, when a ratio of a pitch of the microlens 384 a pitch (or a period) of the pixel region P is 0.3946 or less, a moire is removed from a shot picture.

<Second Condition>

The first condition in order for no moire to happen in a shot picture for the display device 300 according to the second embodiment, 3 microlenses 384a, 384b and 384c having different slanted angles θ1, θ2 and θ3 can be used. Alternatively, as shown in FIG. 13, in the display device 300 according to the second embodiment, 2 microlenses having different slanted angles θ1 and θ2 can be used.

The microlenses 384 of the microlens array 380 might be identical all over the microlens array 380. However, in this case, when the display device 300 is inspected by the inspection apparatus 400, a moire happens in a shot picture. Thus, to remove the moire of the shot picture, it can be preferable that the microlens array 380 is configured with the 2 microlenses 384 having different slanted angles θ1 and θ2, and is can be more preferably that the microlens array 380 is configured with the 3 microlenses 384 having different slanted angles θ1, θ2 and θ3.

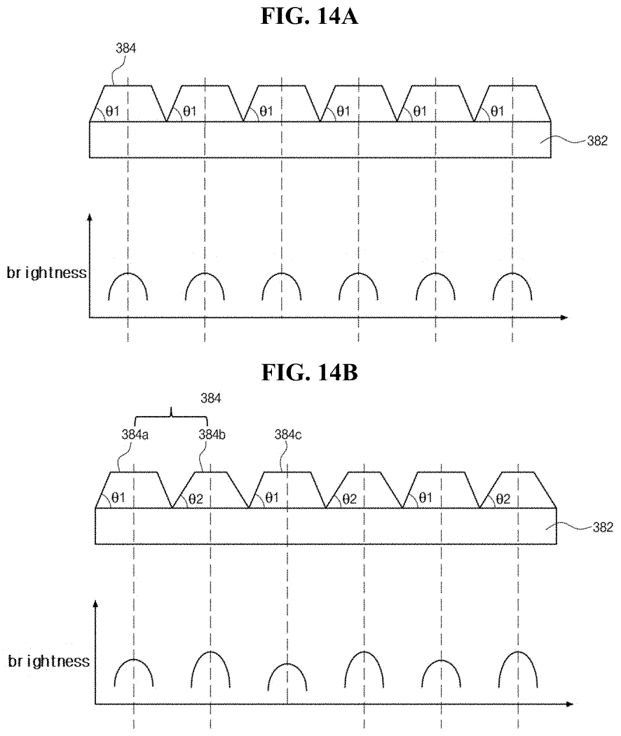

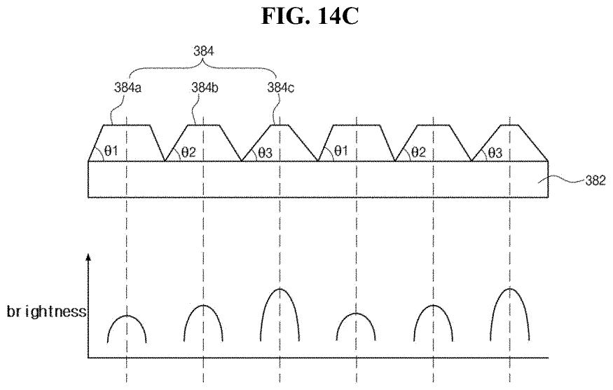

FIG. 14A is a view illustrating a brightness of a picture displayed on a display device in case of microlenses of a microlens array all having equal slanted angles θ1, FIG. 14B is a view illustrating a brightness of a picture displayed on a display device in case of microlenses of a microlens array having 2 different slanted angles θ1 and θ2, and FIG. 14C is a view illustrating a brightness of a picture displayed on a display device in case of microlenses of a microlens array having 3 different slanted angles θ1, θ2 and θ3.

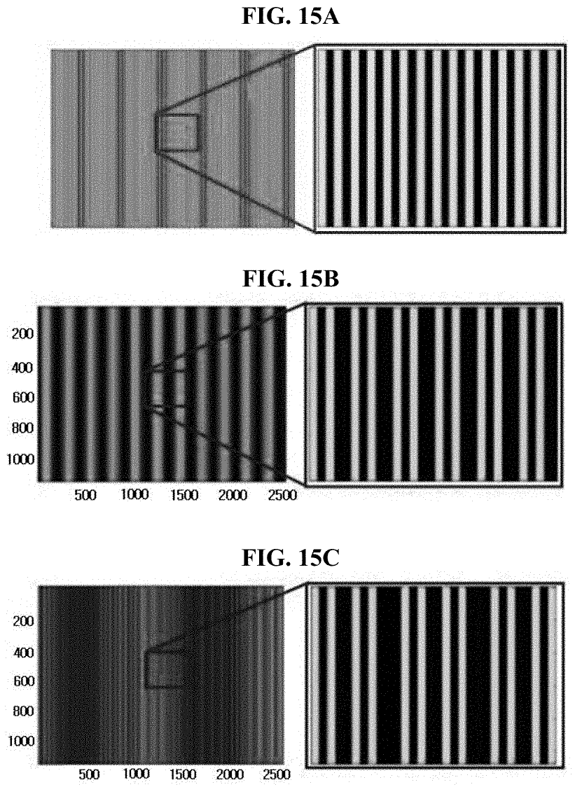

FIG. 15A is a view illustrating an example of a shot picture in case of microlenses of a microlens array all having equal slanted angles θ1, FIG. 15B is a view illustrating an example of a shot picture in case of microlenses of a microlens array having 2 different slanted angles θ1 and θ2, and FIG. 15C is a view illustrating an example of a shot picture in case of microlenses of a microlens array having 3 different slanted angles θ1, θ2 and θ3.

Referring to FIG. 14A, in case of microlenses 384 of a microlens array all having equal slanted angles θ1, brightnesses of images displayed on the display device by the microlenses 384 increase. Because the microlenses 384 of the microlens array all have equal slanted angles θ1 and have equal shapes (i.e., shapes which have equal areas of bottom surfaces and equal areas of top surfaces), increases of brightness by the microlenses 384 are all equal.

Accordingly, images having equal brightnesses are repeated periodically entirely over the display device 300. Because the periodic images of the brightnesses interfere periodically with optical sensors (i.e., camera sensors) arranged periodically in the camera of the inspection apparatus 400, a moire, which has a high brightness region and a low brightness region are produced alternately and periodically, happens strongly in the shot picture, as shown in FIG. 15.

Referring to FIG. 14B, in case of microlenses 384a and 384b of a microlens array having 2 different slanted angles θ1 and θ2, brightnesses of images displayed on the display device by the microlens 384a and 384b increase, but degrees of increase of brightness are different depending on slanted angles, shown in Table 1.

Accordingly, because equal brightnesses are not repeated periodically entirely over the display device 300 but brightnesses having 2 different intensities are repeated entirely over the display device 300, a periodicity of brightness of image is partially lost. Thus, images interfere partially periodically with the optical sensors arranged periodically in the camera of the inspection apparatus 400, and a degree of the interference is reduced, and thus a moire happens at a medium level in the shot picture.

Referring to FIG. 14C, in case of microlenses 384a, 384b and 384c of a microlens array having 3 different slanted angles θ1, θ2 and θ3, brightnesses of images displayed on the display device by the microlens 384a, 384b and 384c increase, but degrees of increase of brightness are different depending on slanted angles, shown in Table 1.

Accordingly, because equal brightnesses are not repeated periodically entirely over the display device 300 but brightnesses having 3 different intensities are repeated entirely over the display device 300, a periodicity of brightness of image is partially lost. Thus, images interfere minutely periodically with the optical sensors arranged periodically in the camera of the inspection apparatus 400, and a degree of the interference is much reduced, and thus a moire happens at a weak level in the shot picture.

As described above, in the display device according to the second embodiment, with the microlens array including the microlenses having 2 different slanted angles θ1 and θ2 or the microlenses having 3 different slanted angles θ1, θ2 and θ3, a moire can be partially or mostly removed from the shot picture of the inspection apparatus 400.

<Third Condition>

The third condition in order for no moire to happen in a shot picture for the display device 300 according to the second embodiment, 3 microlenses 384a, 384b and 384c having different slanted angles θ1, θ2 and θ3 arranged in the microlens array 380 can have different distribution ratios.

Particularly, it is preferable that the first microlens 384a having a slanted angle θ1 of 40°<θ1<50°, the second microlens 384b having a slanted angle θ2 of 25°<θ2<35°, and the third microlens 384c having a slanted angle θ3 of 10°<θ3<20°, and preferably the first microlens 384a having a slanted angle θ1 of 45°, the second microlens 384b having a slanted angle θ2 of 30°, and the third microlens 384c having a slanted angle θ3 of 15° are distributed in a ratio of 10%:10%:80% to 15%:15%:70%.

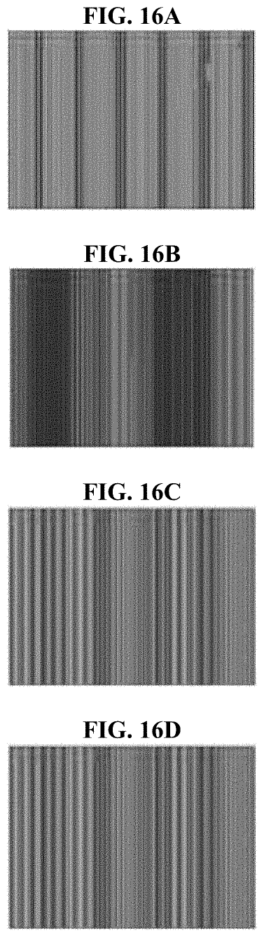

FIG. 16A is a view illustrating an example of a shot picture of an inspection apparatus in case of first to third microlenses 384a, 384b and 384c being distributed at a ratio of 0%:0%:100% (i.e., a structure of all microlenses having equal slanted angles), FIG. 16B is a view illustrating an example of a shot picture of an inspection apparatus in case of first to third microlenses 384a, 384b and 384c being distributed at a ratio of 5%:5%:90%, FIG. 16C is a view illustrating an example of a shot picture of an inspection apparatus in case of first to third microlenses 384a, 384b and 384c being distributed at a ratio of 10%:10%:80%,and FIG. 16D is a view illustrating an example of a shot picture of an inspection apparatus in case of first to third microlenses 384a, 384b and 384c being distributed at a ratio of 15%:15%:70%.

In case of the first to third microlenses 384a, 384b and 384c being distributed at a ratio of 0%:0%:100%, i.e., a structure of all microlenses having equal slanted angles (e.g., 10°<θ3<20°, preferably θ3=15°, a brightness is improved to 135% compared with a display device including no microlenses, as shown in Table 1, but a moire happens at a strong level in a shot picture for the display device, as shown in FIG. 16A.

In case of the first to third microlenses 384a, 384b and 384c being distributed at a ratio of 5%:5%:90%, the microlenses having greater slanted angles θ1 and θ2 increase in ratio. Thus, a degree of improvement of brightness with respect to a brightness of a display device including no microlenses is reduced a little, and a degree of moire is improved a little thus a moire happens at a weak level in a shot picture for the display device, as shown in FIG. 16B.

As described above, in case of the display device with the first to third microlenses 384a, 384b and 384c being distributed at a ratio of 0%:0%:100%, i.e., a structure of all microlenses having equal slanted angles and the display device with the first to third microlenses 384a, 384b and 384c being distributed at a ratio of 5%:5%:90%, a brightness is greatly improved. However, when pictures displayed on these display devices are shot by the inspection apparatus 400 and inspections are conducted, moires happen in the shot pictures. Thus, determination of whether the display devices are defective or not is impossible, and accurately compensating for pictures and displaying pictures of high quality are impossible.

In case of the first to third microlenses 384a, 384b and 384c being distributed at a ratio of 10%:10%:80%, the microlenses having greater slanted angles θ1 and θ2 increase further in ratio. Thus, a degree of improvement of brightness with respect to a brightness of a display device including no microlenses is reduced, but a moire is improved thus no moire happens in a shot picture for the display device, as shown in FIG. 16C.

In case of the first to third microlenses 384a, 384b and 384c being distributed at a ratio of 15%:15%:70%, the microlenses having greater slanted angles θ1 and θ2 increase further in ratio. Thus, a degree of improvement of brightness with respect to a brightness of a display device including no microlenses is reduced, but a moire is improved thus no moire happens in a shot picture for the display device, as shown in FIG. 16D.

Accordingly, In case of the first to third microlenses 384a, 384b and 384c being distributed at a ratio of 10%:10%:80% to 15%:15%:70%, a picture of a high brightness can be displayed on the display device, and a moire happening in the shot picture when inspecting can be prevented.

As described above, in the display device 300 according to the second embodiment of the present invention, the first condition regarding a relation of a pitch of the pixel of the display device 300 to a pitch of the microlens 384 of the display device 300, the second condition regarding the microlenses 384 of the display device 300 having different slanted angles, and the third condition regarding the distribution ratio of the microlenses 384 of the display device 300 having different slanted angles can need to be satisfied.

However, the display device 300 of the second embodiment does not have to satisfy all of the first to third conditions. Even when one or two of the first to third conditions are satisfied, the desired technical effect can be achieved compared with the prior art display device.

In the display device according to the above-described embodiments of the present invention, the polygonal-patterned microlens array is located at the display surface of the display panel, and thus a brightness of the display device can be improved.

Further, because the microlens is formed in the polygonal pattern, a back scattering of a light can be prevented, thus a leakage of an external light reflected in the display panel can be prevented, and thus a visibility of the display device can be improved.

Further, a ratio of the pitch of the microlens to the pitch of the pixel region of the display panel is set to 0.3946 or less, the slanted angles θ1, θ2 and θ3 of the microlenses is set as θ1=45°, θ2=30° and θ3=15°, and the first to third microlenses are distributed at a ratio of 10%:10%:80% to 15%:15%:70%, and a moire happening in a shot picture when a picture displayed on the display device is shot by the inspection apparatus can be prevented. As a result, whether the display device is defective or not when inspecting the display device can be accurately determined, and a compensation of a picture can be accurately made thus a picture of high quality can be realized.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A display device, comprising:
a display panel including a plurality of pixel regions, and configured to display a picture or an image; and
a microlens array disposed on a front surface of the display panel, and including a plurality of microlenses each having a polygonal pattern,
wherein the plurality of microlenses have different slanted angles.

2. The display device of claim 1, wherein the plurality of microlenses include a first microlens and a second microlens which have different slanted angles, and
wherein the first microlens has a slanted angle θ1 which is approximately 25°<θ1<35°, and the second microlens has a slanted angle θ2 which is approximately 10°<θ2<20°.

3. The display device of claim 2, wherein the slanted angle θ1 of the first microlens is 30°, and the slanted angle θ2 of the second microlens is 15°.

4. The display device of claim 1, wherein the plurality of microlenses include a first microlens, a second microlens and a third microlens which have different slanted angles.

5. The display device of claim 4, wherein a ratio of a pitch of the microlens to a pitch of the pixel region of the display panel is 0.3946 or less.

6. The display device of claim 4, wherein the first microlens has a slanted angle θ1 which is approximately 40°<θ1<50°, the second microlens has a slanted angle θ2 which is approximately 25°<θ2<35°, and the third microlens has a slanted angle θ3 which is approximately 10°<θ3<20°.

7. The display device of claim 6, wherein the slanted angle θ1 of the first microlens is 45°, the slanted angle θ2 of the second microlens is 30°, and the slanted angle θ2 of the third microlens is 15°.

8. The display device of claim 7, wherein the first to third microlenses have a distribution ratio of approximately 10%:10%:80% to approximately 15%:15%:70%.

9. The display device of claim 1, wherein the microlens array includes:
a base film attached to a picture display surface of the display panel; and
the plurality of microlenses located on the base film.

10. The display device of claim 1, wherein the microlens array includes the plurality of microlenses formed on a picture display surface of the display panel.

11. The display device of claim 1, wherein the microlens array is located in the display panel.

12. The display device of claim 1, wherein the plurality of microlenses have at least one of a triangular pattern, a quadrangular pattern, a pentagonal pattern, and a hexagonal pattern.

13. The display device of claim 1, wherein the display panel is one of an organic light emitting display panel, an electrophoresis display panel, a mini light emitting diode (LED) display panel, a micro LED display panel, and a tiled type display panel which is configured with a plurality of panels arranged in a tiling manner.

14. A microlens array, comprising:
a base film attached to a display panel configured to display a picture or an image; and
a plurality of microlenses disposed on the base film, each of the plurality of microlenses having a polygonal pattern,
wherein the plurality of microlenses have different slanted angles.

15. The microlens array of claim 14, wherein the plurality of microlenses include a first microlens and a second microlens, and
wherein the first microlens has a slanted angle θ1 which is approximately 25°<θ1<35°, and the second microlens has a slanted angle θ2 which is 1 approximately 0°<θ2<20°.

16. The microlens array of claim 15, wherein the slanted angle θ1 of the first microlens is 30°, and the slanted angle θ2 of the second microlens is 15°.

17. The microlens array of claim 14, wherein the microlenses include a first microlens, a second microlens and a third microlens, and
wherein the first microlens has a slanted angle θ1 which is approximately 40°<θ1<50°, the second microlens has a slanted angle θ2 which is approximately 25°<θ2<35°, and the third microlens has a slanted angle θ3 which is 1 approximately 0°<θ3<20°.

18. The microlens array of claim 17, wherein the slanted angle θ1 of the first microlens is 45°, the slanted angle θ2 of the second microlens is 30°, and the slanted angle θ2 of the third microlens is 15°.

19. The microlens array of claim 18, wherein the first to third microlenses have a distribution ratio of approximately 10%:10%:80% to approximately 15%:15%:70%.

20. The microlens array of claim 17, wherein a ratio of a pitch of the microlens to a pitch of the pixel region of the display panel is 0.3946 or less.
